(19) United States
(12) Patent Application Publication
(10) Pub. No.: US 2002/0062557 A1
(43) Pub. Date: May 30, 2002

(54) Cooler chip fabrication method

(76) Inventor: Tsung-Chih Chen, Taoyuan (TW)

Correspondence Address: DOUGHERTY & TROXELL, Suite 1404, 5205 Leesburg Pike, Falls Church, VA, 22041, US

(21) Appl. No.: 09/725,303

(22) Filed: Nov. 29, 2000

(51) Int. Cl. H05K 3/34; H05K 3/36

(52) U.S. Cl. 29/840; 29/830; 29/846

(57) ABSTRACT

A cooler chip fabrication method includes the steps of (a) making an upper substrate and a bottom substrate with ceramic-resin mixture; (b) screen-printing conductor elements on the substrates; (c) adhering metal plates to the conductor elements of the substrates and then coating the conductor elements with a soldering flux; (d) adhering antimony-bismuth chips to two distal ends of each metal plate of the bottom substrate, keeping the two opposing antimony-bismuth chips of each two adjacent metal plates to show different polarity; (e) detecting and correcting the polarity of the antimony-bismuth chips; (f) fastening the upper substrate to the antimony-bismuth chips at the bottom substrate, so as to form a semi-finished cooler chip; and (g) dying antimony-bismuth chips semi-finished cooler chip into a finished cooler chip through a baking process.

### BACKGROUND OF THE INVENTION

The present invention relates to a method of fabricating cooler chips and, more particularly, to such a method, which uses antimony-bismuth chips for making a cooler chip.

Antimony-bismuth chips are intensively used in space technology (for example, heat-insulating chips for space shuttle). Nowadays, industrial application of antimony-bismuth chips has been realized. For example, advanced cooler chips use antimony-bismuth chips. However, because the encapsulation of antimony-bismuth chip type cooler chips is achieved by labor, the fabrication efficiency is not satisfactory.

### SUMMARY OF THE INVENTION

The present invention has been accomplished to provide an antimony-bismuth chip type cooler chip fabrication method, which shortens the cooler chip fabrication time and, greatly improves the quality of the finished products. According to the present invention, conductor elements are screen-printed on an upper substrate and a bottom substrate at predetermined locations, and then metal plates are respectively adhered to the conductor elements and coated with a soldering flux, and then antimony-bismuth chips are adhered to the metal plates of the bottom substrate and the polarity of the installed antimony-bismuth chips are checked, and then the upper substrate is fastened to the antimony-bismuth chips at the bottom substrate. After drying through a baking process, a finished cooler chip is thus obtained.

### BRIEF DESCRIPTION OF THE DRAWINGS

FIG. 1 is a cooler chip fabrication flow chart according to the present invention.

FIG. 2 shows the upper substrate and the bottom substrate of the cooler chip extended out according to the present invention.

FIG. 3 is an exploded view of a part the cooler chip according to the present invention.

FIG. 4 is a sectional view of a part of the cooler chip according to the present invention.

FIG. 5 is a perspective view of a part of the cooler chip according to the present invention.

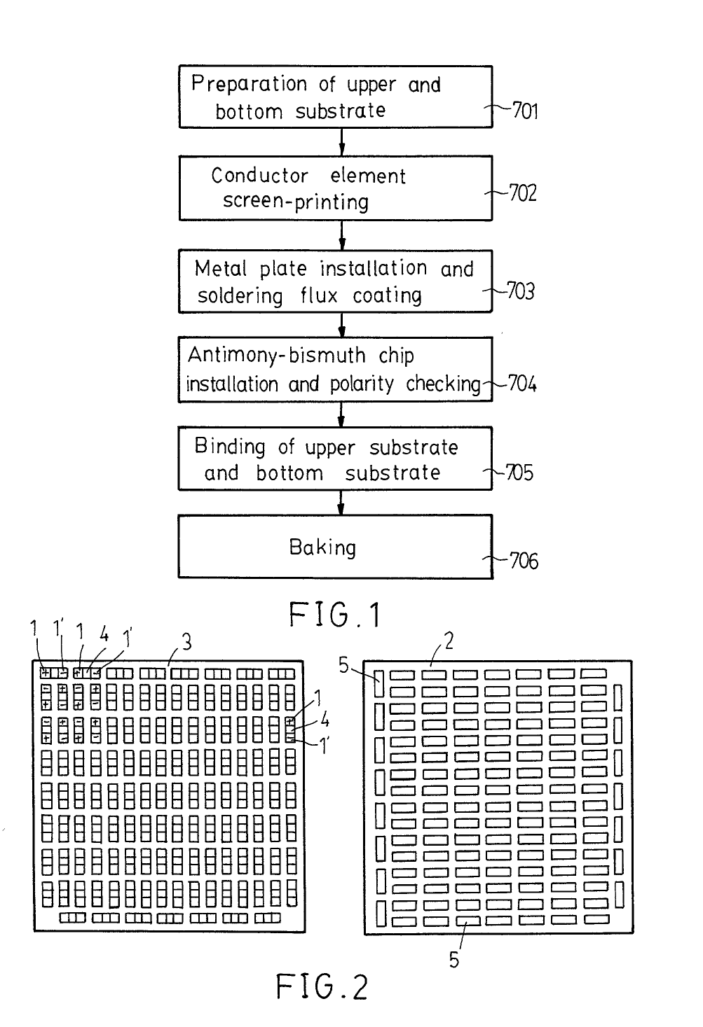

### DETAILED DESCRIPTION OF THE PREFERRED EMBODIMENT

The cooler chip fabrication method of the present invention comprises the steps of:

(1) Using ceramic-resin mixture to make an upper substrate and a bottom substrate;

(2) Screen-printing conductor elements on the upper substrate and the bottom substrate;

(3) Adhering metal plates to the conductor elements at the upper substrate and the bottom substrate, and then coating a soldering flux on the metal plates;

(4) Adhering antimony-bismuth chips to two distal ends of each metal plate of the bottom substrate, keeping the two opposing antimony-bismuth chips of each two adjacent metal plates to show different polarity;

(5) Detecting the polarity of the antimony-bismuth chips at the bottom substrate and correcting the polarity;

(6) Pressing the upper substrate onto the bottom substrate so as to form a semi-finished cooler chip;

(7) Drying the semi-finished cooler chip into a finished cooler chip through a baking process.

Referring to FIGS. from 1 through 5, the method of the present invention comprises the steps of:

(701) Using ceramic-resin mixture to make an upper substrate 2 and a bottom substrate 3;

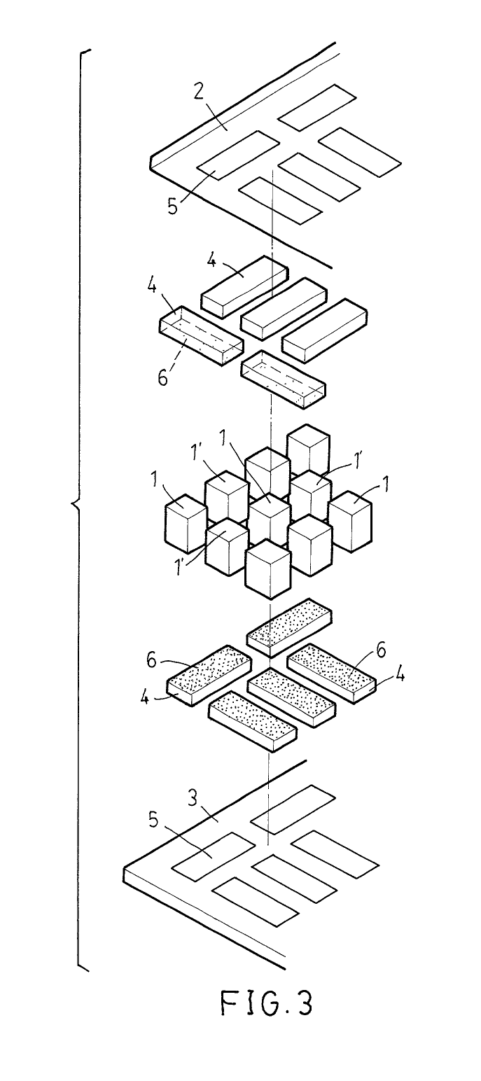

(702) Screen-printing transverse and longitudinal rows of conductor elements 5 on the inner side of the upper substrate 2 as well as the bottom substrate 3, keeping the conductor elements of the upper substrate 2 and the conductor elements of the bottom substrate 3 in stagger (see FIGS. 2 and 3);

(703) Using a vibration feeder to guide metal plates 4 into registers corresponding to the positions of the conductor elements 5 on the upper substrate 2 and the bottom substrate 3, and then adhering the metal plates 4 to the conductor elements 5, and then coating a soldering flux 6 on the metal plates 4 (see FIGS. 2 and 3)

(704) Using a vibration feeder to guide antimony-bismuth chips 1 and 1′ of different polarity into registers, and then adhering the antimony-bismuth chips 1 and 1′ to two distal ends of each metal plate 4 of the bottom substrate 3, keeping the two opposing antimony-bismuth chips 1 and 1′ of each two adjacent metal plates 4 to show different polarity (see FIGS. 2 and 3);

(705) Using a probe to detect the polarity of the antimony-bismuth chips 1 and 1′, and then removing extra chips of incorrect polarity from the metal plates 4, and then attaching chips of correct polarity to the metal plates 4 to make correction;

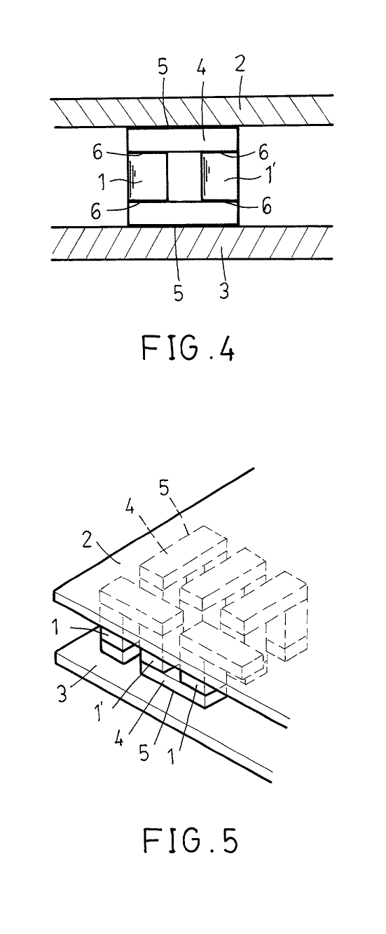

(706) Pressing the upper substrate 2 onto the bottom substrate 3, enabling the antimony-bismuth chips 1 and 1′ to be respectively connected to the soldering flux 6 at the metal plates 4 of the upper substrate 2, so as to form a semi-finished cooler chip (see FIGS. 4 and 5); and

(707) Baking the semi-finished cooler chip in a stove to harden the structure, so as to obtain a finished cooler chip.

It is to be understood that the drawings are designed for purposes of illustration only, and are not intended for use as a definition of the limits and scope of the invention disclosed.

What the invention claimed is:

1. A cooler chip fabrication method comprising the steps of:
(1) Using ceramic- resin mixture to make an upper substrate and a bottom substrate;
(2) Screen-printing conductor elements on said upper substrate and said bottom substrate;
(3) Adhering metal plates to the conductor elements at said upper substrate and said bottom substrate, and then coating a soldering flux on said metal plates;
(4) Adhering antimony-bismuth chips to two distal ends of each metal plate of said bottom substrate, keeping the two opposing antimony-bismuth chips of each two adjacent metal plates to show different polarity;
(5) Detecting the polarity of the antimony-bismuth chips at said bottom substrate and correcting the polarity;
(6) Pressing said upper substrate onto said bottom substrate to keep said antimony-bismuth chips connected between the metal plates at said upper substrate and the metal plates at said bottom substrate, so as to form a semi-finished cooler chip; and
(7) Drying antimony-bismuth chips semi-finished cooler chip into a finished cooler chip through a baking process.
